(19) United States
(12) Patent Application Publication
(10) Pub. No.: US 2011/0195196 A1
(43) Pub. Date: Aug. 11, 2011

(54) METHOD FOR MANUFACTURING TRANSPARENT OXIDE ELECTRODE USING ELECTRON BEAM POST-TREATMENT

(76) Inventor: Yong Hwan Kim, Gyeonggi-do (KR)

(21) Appl. No.: 13/122,964

(22) PCT Filed: Oct. 5, 2009
(86) PCT No.: PCT/KR09/05676

§ 371 Date: Apr. 6, 2011

(30) Foreign Application Priority Data
Oct. 6, 2008 (KR) 10-2008-0097530

(51) Int. Cl. C23C 16/40; B05D 3/06; C23C 14/34; C23C 14/46; C23C 14/08; C23C 4/10; C25D 5/48

(52) U.S. Cl. 427/453; 427/551; 204/192.29; 204/192.11; 427/529; 205/220

(57) ABSTRACT

The present invention relates to a method for manufacturing a transparent oxide electrode using an electron beam post-treatment. The method for manufacturing a transparent oxide electrode comprises the steps of: (a) forming a thin film for the transparent anode on a substrate; and (b) irradiating an electron beam to the surface of the thin film for the transparent oxide electrode. The method of the present invention is characterized in that no additional heat treatment process is performed after step (a). The method for manufacturing a transparent oxide electrode according to the present invention does not perform a high-temperature heat treatment process but rather performs a low-temperature electron beam irradiation process as a post-treatment, thus obtaining a transparent oxide electrode having excellent characteristics in case where the substrate is made of glass, Pyrex, quartz or even a polymer material which has a low resistance against heat.

### TECHNICAL FIELD

The present invention relates to a method for manufacturing a transparent oxide electrode, and more particularly, to a method for manufacturing a transparent anode by forming a thin film for the transparent oxide electrode on a substrate and post-treating the thin film for the transparent anode using an irradiation of an electron beam to the surface of the thin film for the transparent oxide electrode to thereby improve performance of the electrode.

### BACKGROUND ART

In general, materials used as a transparent oxide electrode include indium tin oxide (ITO), indium zinc oxide (IZO), tin oxide (SnO₂), antimony-doped tin oxide (ATO), fluorine-doped tin oxide (FTO), indium oxide, zinc oxide, gallium zinc oxide (GZO), indium gallium zinc oxide (IGZO), cadmium oxide, phosphorus-doped tin oxide, ruthenium oxide, aluminum-doped zinc oxide and a combination of the foregoing. If such materials of the transparent oxide electrode are used to form a thin film, a liquid crystal display (LCD), an organic light emitting diode (OLED), a plasma display panel (PDP), electroluminescent (EL) display, LD, or light emitting diode (LED) display or a transparent anode of optical elements, solar cell, or a touch screen is manufactured since the materials are conductive and transparent with respect to visible ray.

Among the transparent oxide electrode materials, an ITO thin film is used most generally. The ITO thin film has a band gap of 2.5 eV or more and is transparent with respect to visible ray, and mainly deposited by sputtering. The sputtering process for forming the ITO thin film is as follows: (i) A substrate is placed in a vacuum chamber in a vacuum of 10⁻³ Torr and then the internal temperature is raised to 200° C. to 300° C.; and (ii) oxygen and argon gas are supplied to the vacuum chamber, and DC/RF power is applied to an ITO target facing the substrate to generate plasma, and the ITO target is sputtered by Ar positive ion accelerated by the voltage applied to the ITO target. Then, the sputtered ITO particles are deposited on the substrate. The process of depositing other transparent oxide electrode materials by sputtering is the same as the foregoing ITO generating process except for the target material.

After the transparent oxide electrode material is deposited on the surface of the thin film by the foregoing process to form a thin film for the transparent oxide electrode, the substrate is heat-treated in the same chamber or moved to another chamber and heat-treated as a post-treatment process. The heat-treatment is performed at a temperature of approximately 200° C. to 300° C. The heat treatment as a post-treatment improves conductivity of the thin film for the transparent oxide electrode, makes a compact thin film, improves a surface roughness and enhances light transmittivity.

However, the foregoing high-temperature heat treatment damages the substrate due to thermal imbalance if the substrate includes glass. If the substrate is weak to heat such as polyethylene terephthalate (PET) or polycarbonate, the substrate is damaged by the high-temperature heat treatment or the thin film is peeled by stress arising from the difference of coefficients of thermal expansion between a polymer material and an ITO thin film as the temperature of the substrate rises.

The ITO anode thin film which is manufactured by conventional sputtering has less oxygen therein than indium, and thus a reactive sputtering is performed to supply a small quantity of oxygen such as argon gas during the sputtering process. However, according to the reactive sputtering process, properties of the thin film drastically deteriorate if oxygen is supplied beyond an optimal quantity. If oxygen in the thin film does not have its optimum value, conductivity and transmittivity of the thin film with respect to visible ray become worse, which is a material weakness of the transparent oxide electrode.

Also, the thin film for the transparent oxide electrode which is manufactured by the conventional sputtering has great surface roughness, and is not appropriate to be used in the field where the surface smoothness is very important. In this case, even if heat treatment is performed after forming the thin film for the transparent oxide electrode, the surface smoothness does not improve sufficiently. Accordingly, if the ITO thin film applies to the OLED, a dark spot arises from a part of pixels not emitting light due to the projection of the surface.

To improve the surface roughness, Japanese Patent Publication No. 9-120890 discloses “Organic Electro-Luminescent Display Device and Manufacturing Method Thereof.” According to the above invention, the surface roughness improves by cleansing remainders from the surface with an acid solution such as nitric acid, sulphuric acid and hydrochloric acid after an additional polishing process is performed.

Such additional post treatment includes high-temperature heat treatment and plasma post treatment using oxygen and argon gas, which etches the surface with oxygen ion as an additional process for improving the surface after the heat-treatment process. However, this treatment requires additional time and incurs additional expenses.

The post-treatment of the transparent oxide electrode includes heat-treatment and UV treatment. The heat treatment is generally used and has limitation in size and type of substrates since it raises the temperature of the substrate to thereby raise the temperature of the thin film provided on the substrate. In particular, in the case of a large glass, the distribution of temperature should be uniform in every spot, and it takes long time to raise, maintain and lower temperature. Also, a polymer film which is weak to heat has its limitation in raising temperature. Thus, an anode which is deposited on the polymer film is limited in improving conductivity and making a compact thin film. The UV treatment has a limited effect due to restricted energy of UV heat. Such effect is hardly expected in the case of a ZnO thin film which requires high-temperature heat treatment.

### DISCLOSURE

### Technical Problem

In order to achieve the object of the present invention, a manufacturing method for a transparent oxide electrode using an electron beam post-treatment to improve properties of the transparent oxide electrode without a high-temperature heat treatment is provided.

### Technical Solution

In order to achieve the object of the present invention, a method for manufacturing a transparent oxide electrode using an electron beam post-treatment comprises steps of (a) forming a thin form for a transparent oxide electrode on a substrate; and (b) irradiating an electron beam to a surface of the thin film for the transparent oxide electrode, without any additional heat-treatment process after the step (a).

The substrate according to the method for transparent oxide electrode with the foregoing characteristics comprises one of oxide, nitride and compound semiconductor (GaN, GaAs or the like) including glass, Pyrex, quartz, polymer, silicon, and sapphire. The polymer includes one of polyethylene terephthalate (PET), polyethylene naphthalate (PEN), polyethersulfone (PES), polyimide (PI), polycarbonate (PC) and PTFE. The thin film for the transparent anode comprises one of indium tin oxide (ITO), indium zinc oxide (IZO), tin oxide (SnO₂), antimony-doped tin oxide (ATO), fluorine-doped tin oxide (FTC)), indium oxide, zinc oxide, gallium zinc oxide (GZO), indium gallium zinc oxide (IGZO), cadmium oxide, phosphorus-doped tin oxide, ruthenium oxide, aluminum-doped zinc oxide and a combination thereof.

The step (b) of the method for manufacturing the transparent oxide electrode may be performed in an oxygen atmosphere by generating a micro oxygen atmosphere during a process of irradiating an electron beam.

### Advantageous Effect

A method for manufacturing a transparent oxide electrode according to the present invention may manufacture an excellent transparent oxide electrode even with a polymer type substrate which has low resistance to heat, by irradiating low-temperature electron beam without any heat-treatment as a post-treatment. Also, the electron beam which is needed for the post-treatment is generated by using plasma and may be used for a large size substrate. Thus, the electron beam irradiation may uniformly process a large surface of the thin film for the transparent oxide electrode.

Also, the method for manufacturing the transparent oxide electrode according to the present invention increases reactivity and fluidity of particles by supplying energy to indium or tin particles of the thin film for the transparent oxide electrode with the irradiation of the electron beam to the surface of the thin film, and facilitates diffusion of atoms in a bulk of the surface and inside the thin film. If the temperature of the surface of the substrate is low, columnar growth including lots of pores is facilitated in case additional energy particles such as an electron beam is not irradiated. However, the electron beam enables a compact thin film without pores or defects. Thus, the transparent oxide electrode manufactured according to the present invention has improved conductivity, smoothness, and transmittivity.

In the case of a TFT-LCD which is manufactured by a TFT array substrate formed on a glass substrate and a color filter substrate formed on the glass substrate, a pixel electrode of the TFT array substrate and a common electrode of the color filter substrate may be changed to a transparent oxide electrode, e.g., an ITO electrode. In the case of an LCD which is manufactured by the foregoing post-treatment may reduce a driving voltage of the TFT-LCD.

The method for manufacturing the transparent oxide electrode according to the present invention has a process of forming a thin film for a transparent oxide electrode, and a post-treatment process irradiating electron beam, which are separate processes. The thin film for the transparent oxide electrode at the first step may be formed in various methods. Accordingly, the thin film for the transparent oxide electrode may be deposited by selecting an optimal method depending on a material of the thin film for the transparent oxide electrode, regardless of the post-treatment process. Also, the process of forming the thin film for the transparent oxide electrode may improve throughput and enable bulk production at reasonable costs by selecting a speedy deposition method suitable for the purpose of use of the thin film. The transparent oxide electrode which is manufactured by the various methods as above may be optimal and have improved performance by controlling electron beam energy, flux of energy beam and time even if the properties of the transparent oxide electrode vary depending on the manufacturing method or materials.

The electron beam treatment may bring good results only by post-treatment after the deposition of the thin film even if the substrate is not heated during a manufacturing process. Also, if energy and flux of electron beam increases during the electron beam post-treatment, processing time may be reduced and a transparent oxide electrode may be manufactured at a faster speed that a heat-treatment method.

As the electron beam is irradiated to the thin film of the surface of the substrate, only the surface of the thin film is heated. Thus, if suitable energy and time are selected and the substrate is heated, the temperature of the substrate is maintained as low and a surface treatment is available.

### BRIEF DESCRIPTION OF DRAWINGS

FIG. 1 illustrates sputtering and an electron beam treatment implemented sequentially in two chambers to explain a method for manufacturing a transparent oxide electrode of an embodiment of the present invention.

FIG. 2 is a graph which illustrates a reduction of resistivity of a transparent oxide electrode which varies depending on an irradiated electron beam energy with respect to an increase of flux of electrons by applying RF power of 200 W, 300 W and 400 W to an electron beam source extracting electron from RF plasma, in the transparent oxide electrode manufactured by sputtering in the method for manufacturing the transparent oxide electrode of the embodiment of the present invention.

FIG. 3 is a graph which illustrates a resistivity of a transparent oxide electrode varying depending on a change of energy of an electron beam with respect to two samples of 30 and 60 minute electron beam-irradiating time if RF power of 300 W is consistently applied to the electron beam source, in the transparent oxide electrode manufactured by sputtering in the method for manufacturing the transparent anode of the embodiment of the present invention.

FIG. 4 is a graph which compares change of sheet resistance as a result of post-treatment by varying beam energy while the treatment time is set at 10 minutes equally to thereby compare the effect of an electron beam and argon ion beam to an IZO thin film.

FIG. 5 is a graph which illustrates a sheet resistance as a result of irradiating an electron beam with 500 eV energy equally to an IZO thin film by varying time.

FIG. 6 is a graph which illustrates a change of transmittivity of an IZO thin film as a result of irradiating an electron beam with 500 eV energy equally to an IZO thin film by varying time.

### BEST MODE

Hereinafter, a method for manufacturing a transparent oxide electrode using an electron beam post-treatment according to a preferable embodiment of the present invention will be described.

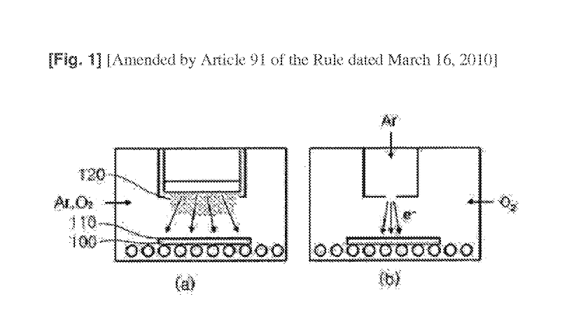

FIG. 1 illustrates an inside of a chamber to explain an example of a method for manufacturing a transparent oxide electrode of an embodiment of the present invention. Referring to FIG. 1, the method for manufacturing the transparent oxide electrode comprises the steps of: (a) forming a thin film for the transparent oxide electrode 110 on a substrate provided in a chamber by using RF/DC plasma 120; and (b) irradiating an electron beam to the surface of the thin film for the transparent oxide electrode and post-treating the thin film without an additional heat treatment process after moving the substrate 100 to another chamber. As shown in FIG. 1, the steps of (a) and (b) may be performed sequentially in a single chamber, or sequentially performed in sequential chambers or may be separately performed not in sequence. Hereinafter, the above processes will be described in more detail.

The step of forming the thin film for the transparent oxide electrode 110 on the substrate 100 may include depositing a transparent anode material 120 on the surface of the substrate 100 in a vacuum, coating the surface of the substrate 100 with the transparent oxide electrode material 120 in the air or coating the substrate 100 in a solution. The deposition of the transparent oxide electrode material 120 on the surface of the substrate 100 in a vacuum includes RF/DC sputtering, ion beam sputtering, chemical vapor deposition (CVD), low pressure chemical vapor deposition (LPCVD), plasma enhanced chemical vapor deposition (PECVD), vacuum evaporation, E-beam evaporation, ion-plating, pulsed laser deposition, powder vacuum spraying or the like. The method of coating the transparent oxide electrode material 120 on the surface of the substrate 100 in the air includes spin coating, spraying or spray pyrolysis, ink-jet printing, painting or the like. The method of coating the surface of the substrate 100 with the transparent oxide electrode material 120 in a solution includes sol-gel process, electroplating, dipping or the like.

The substrate 100 may include one of oxide, nitride and compound semiconductor (GaN, GaAs or the like) including glass, Pyrex, quartz, polymer, silicon, and sapphire. In particular, the polymer may include one of polyethylene terephthalate (PET), polyethylene naphthalate (PEN), polyethersulfone (PES), Polyimide (PI), Polycarbonate (PC) and polytetrafluoroethylene (PTFE).

The transparent oxide electrode material 120 may include one of ITO, IZO, SnO₂, FTO, In₂O₂, zinc oxide, GZO, IGZO, cadmium oxide, phosphorus-doped tin oxide, ruthenium oxide, aluminum-doped zinc oxide and a combination of the foregoing.

The method of generating the electron beam to be irradiated at the step of the post-treatment of the surface of the transparent oxide electrode may include a hot filament in which a tungsten filament is heated, receives a negative DC voltage to emit a thermoelectron and extracting and accelerating electron from shielded plasma.

The hot filament is a method of supplying alternating current to heat a filament such as tungsten and emitting thermoelectron having energy by applying negative DC electron to the filament. This method may heat the substrate by the heat of the filament itself, and the filament is easily broken if heated by this method. As the filament is oxidized by gas such as oxygen, this method has a limitation in usage, and the filament may contaminate the substrate if sputtered by collision of ion. Also, the electron beam is less uniform to process a large size substrate. However, this method is appropriate for testing a small size substrate at reasonable costs.

The method of generating and shielding plasma and extracting and accelerating an electron from the plasma may supplement the weakness of the hot filament method. Also, large size source is available and a large size substrate may be uniformly processed if the source is scanned vertically to the substrate. The power which is used to generate plasma may include medium frequency (MF), high frequency (HF), radio frequency (RF), ultra high frequency (UHF) or microwave, or capacitive, inductive, inductively coupled plasma (ICP), electron cyclotron resonance (ECR), helical, helicon, hollow cathode, or hot filament according to type of electron or antenna, or high pressure plasma such as atmospheric pressure plasma.

At the step of electron beam post-treatment, only the electron beam may be irradiated without supply of additional gas, or electron beam may be irradiated under the oxygen atmosphere while oxygen gas is concurrently supplied as in FIG. 1.

As described above, the manufacturing method according to the present invention prevents thermal damage, deformation or destruction of the substrate by irradiating only the electron beam without the high temperature heat-treatment process after forming the transparent oxide electrode.

To identify the performance of the ITO thin film according to the present invention, an ITO thin film was formed by an RF sputter and post-treated by the electron beam. Then, resistivity of the ITO thin film was measured. The ITO thin film was deposited by RF power with pressure of 7.0E-3 torr by applying Ar 30 sccm within the chamber. The substrate included eagle 2000 glass, and was not additionally heated, and the thickness of the deposited thin film was 150 nm.

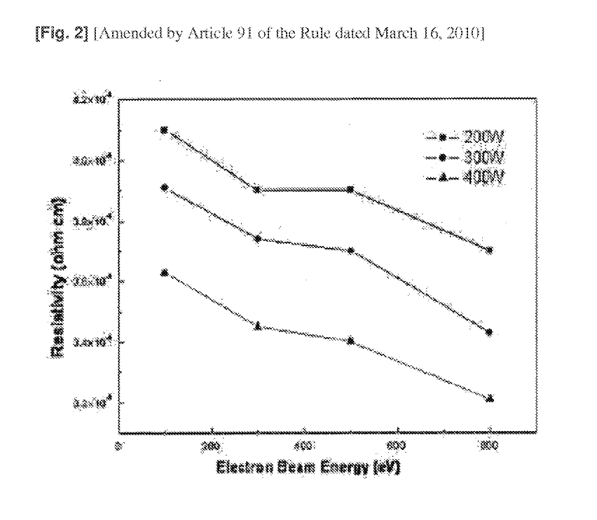

FIG. 2 is a graph which illustrates a reduction of resistivity of a transparent oxide electrode which varies depending on an irradiated electron beam energy with respect to an increase of flux of electrons by applying RF power of 200 W, 300 W and 400 W to an electron beam source extracting electron from RF plasma. The electron beam-irradiating time was uniformly 30 minutes. As in FIG. 2, the more the electron beam energy is, the less the resistivity of the transparent electron becomes. If the RF power of the electron beam increases to raise the flux of the electron beam, the resistivity of the transparent electron decreases.

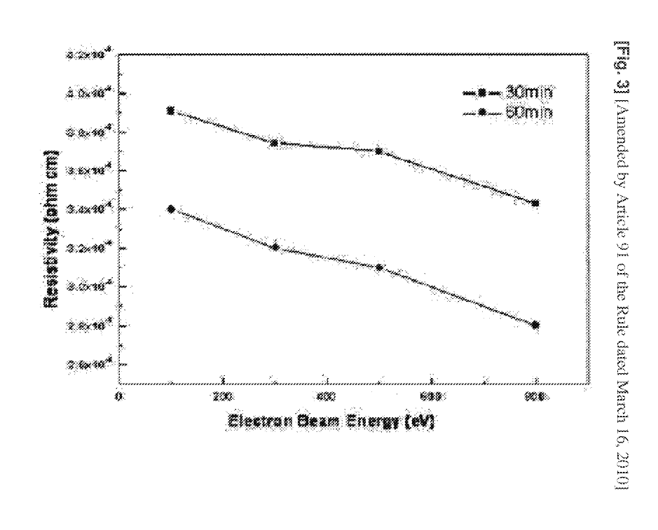

FIG. 3 is a graph which illustrates a resistivity of a transparent oxide electrode varying depending on a change of energy of an electron beam with respect to two samples of 30 and 60 minute electron beam-irradiating time if RF power of 300 W is consistently applied to the electron beam source in the transparent oxide electrode. As in FIG. 3, the longer the irradiation time is, the less the resistivity of the transparent oxide electrode becomes. Accordingly, as the irradiated electron beam energy increases, the resistivity of the transparent oxide electrode decreases.

To identify the performance of the IZO thin film according to the present invention, similarly to the sputtering method, the 100 nm IZO thin film is deposited on a soda-lime glass and post-treated by an electron beam to measure a sheet resistance of the IZO thin film.

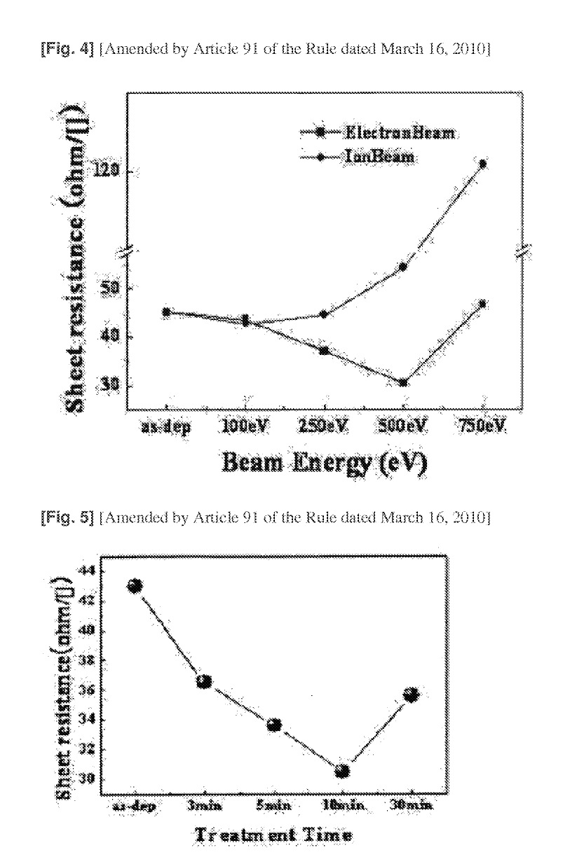

FIG. 4 is a graph which compares a change of sheet resistance as a result of a post-treatment by varying beam energy while the treatment time is set at 10 minutes equally to thereby compare the effect of the electron beam and an argon ion beam with respect to an IZO thin film. Referring to FIG. 4, the value of sheet resistance increases as the energy argon ion beam energy rises. This is because the IZO thin film is etched by damage arising from a collision cascade due to collision of relatively heavy ions compared to the former case even if energy is equal. In the case of electron beam irradiation, the sheet resistance has a minimum value at 500 eV energy. As energy increases, the properties of the thin film improve by collision effect of the electron beam. It was found that indium which has a relatively lower melting point than other elements are extracted by bombardment induced segregation so that the sheet resistance rises.

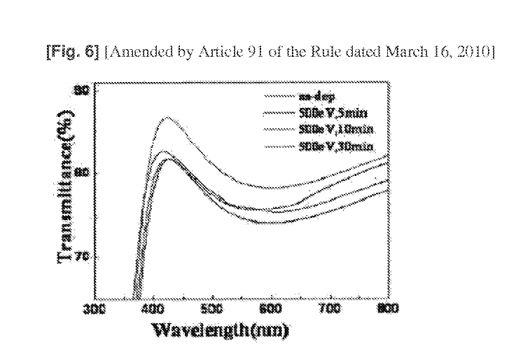

FIG. 5 is a graph which illustrates a sheet resistance as a result of irradiating an electron beam with 500 eV energy equally to an IZO thin film by varying time. As in FIG. 5, an optimal IZO thin film can be obtained for ten minute processing time. FIG. 6 is a graph which illustrates a change of transmittivity of an IZO thin film as a result of irradiating an electron beam with 500 eV energy equally to an IZO thin film by varying time. As in FIG. 6, optimal transmittivity is obtained for ten minute processing time, which is the same as the variation of the sheet resistance value.

Although the present invention has been described with reference to the embodiment described above, it is not limited to the embodiment, and the present invention may be modified in various ways without deviating from the scope of the present invention.

### INDUSTRIAL APPLICABILITY

A method for manufacturing a transparent anode according to the present invention may be widely used in a process for manufacturing a transparent oxide electrode or a semiconductor oxide for an OLED, a TFT, an LCD, a PDP, an LED, an LD, oxide semiconductor, a solar cell, a touch screen or the like.

1. A method for manufacturing a transparent oxide electrode using an electron beam post-treatment comprising:
(a) forming a thin film for the transparent oxide electrode on a substrate; and
(b) irradiating an electron beam to a surface of the thin film for the transparent oxide electrode.

2. The method according to claim 1, wherein an additional heat treatment process is not performed after the step (a).

3. The method according to claim 1, wherein the substrate comprises one of oxide, nitride and compound semiconductor comprising glass, Pyrex, quartz, polymer, silicon and sapphire.

4. The method according to claim 1, wherein the polymer comprises one of polyethylene terephthalate (PET), polyethylene naphthalate (PEN), polyethersulfone (PES), Polyimide (PI), Polycarbonate (PC), and PTFE.

5. The method according to claim 1, wherein the step (b) comprises irradiating only the electron beam without any injection of gas or irradiating the electron beam in the oxygen atmosphere.

6. The method according to claim 1, wherein the thin film for the transparent oxide electrode comprises one of indium tin oxide (ITO), indium zinc oxide (IZO), tin oxide (SnO₂), antimony-doped tin oxide (ATO), fluorine-doped tin oxide (FTC)), indium oxide, zinc oxide, gallium zinc oxide (GZO), indium gallium zinc oxide (IGZO), cadmium oxide, phosphorus-doped tin oxide, ruthenium oxide, aluminum-doped zinc oxide and a combination thereof.

7. The method according to claim 1, wherein the steps (a) and (b) are performed sequentially in a same chamber or, sequentially performed in sequential chambers by moving the substrate or performed by additional unsequential processes.

8. The method according to claim 1, wherein the method of forming the thin film for the transparent oxide electrode at the step (a) comprises one of depositing the thin film on a surface of the substrate in a vacuum, coating the thin film with a solution and coating the thin film on a surface of the substrate in the air.

9. The method according to claim 8, wherein the depositing the transparent oxide electrode material on the surface of the substrate in the vacuum comprises one of RF/DC sputtering, ion beam sputtering, chemical vapor deposition (CVD), low pressure chemical vapor deposition (LPCVD), plasma enhanced chemical vapor deposition (PECVD), vacuum evaporation, E-beam evaporation, ion-plating, pulsed laser deposition, and powder vacuum spraying, and the method of coating the transparent oxide electrode material on the surface of the substrate in the air comprises one of spin coating, spraying or spray pyrolysis, ink-jet printing and painting, and the method of coating the surface of the substrate 100 with the transparent anode material 120 in a solution comprises one of sol-gel process, electroplating and dipping.

10. The method according to claim 1, wherein the method for manufacturing the transparent oxide electrode using the electron beam post-treatment applies to manufacturing one of an organic light emitting diode (OLED) display, a thin film transistor (TFT), a liquid crystal display (LCD), a plasma display panel (PDP), a light emitting diode (LED), LD, compound semiconductor, solar cell and a touch screen.

11. The method according to claim 1, wherein the electron beam at the step (b) is generated by one of a hot filament method by which negative DC power is applied to a heated filament to emit thermoelectron and a method of extracting and accelerating an electron from shielded plasma.

12. The method according to claim 1, wherein the electron beam at the step (b) is generated by shielding generated plasma and extracting and accelerating an electron from the shielded plasma, and an alternating frequency of the power generating the plasma comprises one of medium frequency (MF), high frequency (HF), radio frequency (RF), ultra high frequency (UHF) or microwave, and the electrode of the power or antenna comprises one of capacitive, inductive, inductively coupled plasma (ICP), electron cyclotron resonance (ECR), helical, helicon, hollow cathode and hot filament or uses atmospheric plasma.
